(19) United States
(12) Patent Application Publication
(10) Pub. No.: US 2012/0188031 A1
(43) Pub. Date: Jul. 26, 2012

(54) Programmable high-frequency high-gain equalizer for digital display interfaces

(75) Inventors: Xiaojiang Wu, Wuxi (CN); Yiqin Meng, Wuxi (CN)

(73) Assignee: Sigmamix Semiconductor, Inc., Wuxi (CN)

(21) Appl. No.: 12/931,059

(22) Filed: Jan. 25, 2011

(51) Int. Cl. H04B 3/14; H03F 3/191

(52) U.S. Cl. 333/28 R; 330/304

(57) ABSTRACT

There is provided a programmable high-frequency high-gain equalizer for digital display interfaces comprising, two pairs of current sources; two pairs of transistors arranged as two differential pairs, each transistor connected to a different one of the current sources; and a pair of a negative impedance resistors connected to the two pairs of two differential pairs; and a pair of capacitive and programmable resistive degeneration connected to the two pairs of two differential pairs to optimize the equalizer gain.

### FIELD OF THE INVENTION

The present invention relates to an equalizer used in a receiver. More particularly, the present invention relates to compensate the channel frequency-dependent loss of an equalizer used in a receiver in digital display interfaces.

### BACKGROUND

FIG. 1 illustrates a typical transmitter/receiver channel link 100 in a digital display interface. The transmission path medium 101, which includes the cable 106, packages 104, 108 and the load capacitances at the channel nodes 103, 105, 107, 109, has a low pass filter LPF characteristic. The transmitted signal frequency is limited by the transmission path medium 101. The frequency-dependent loss produces inter-symbol interference (ISI) and increases bit-error-rate (BER). In addition, the transmitted signal at node 109 is further corrupted during transmission by noise 111 induced by the transmission path medium 101. The higher the signal frequency is, the higher the degradation of the signal is. For a high-speed and long-cable digital display interface, applying equalization at the receiver is needed to compensate for the frequency-dependent loss, reduce ISI and improve the BER. The equalizer 110 regenerates the transmitted signal at node 109 by providing gain to compensate for the frequency-dependant losses caused by the transmission path medium 101 while preferably minimizing the effect of noise 111. Within the equalizer is a filter that exhibits a high pass characteristic and, more specially, has an inverse frequency response to that of the transmission path medium 101. As a result, the transmitter/receiver channel link 100 achieves a higher bandwidth. Conventional equalizers do not have enough bandwidth and gain that is required for today's applications. Therefore, there is a need for an improved receiver equalizer.

### SUMMARY OF THE INVENTION

In accordance with the invention, there is provided a programmable high-frequency high-gain equalizer for digital display interfaces. Specific embodiments of the invention will now be described, by way of example only, with reference to the accompanying drawings, in which:

### BRIEF DESCRIPTION OF THE DRAWINGS

FIG. 1 is a schematic block diagram illustrating a typical Tx/Rx channel link in a digital display interface;

FIG. 2 is a simplified schematic diagram of an equalizer (without impedance control cells) according to a preferred embodiment of the present invention;

FIG. 3 is a schematic diagram of a programmable impedance control cell that makes up part of the FIG. 2 embodiment.

### DETAILED DESCRIPTION

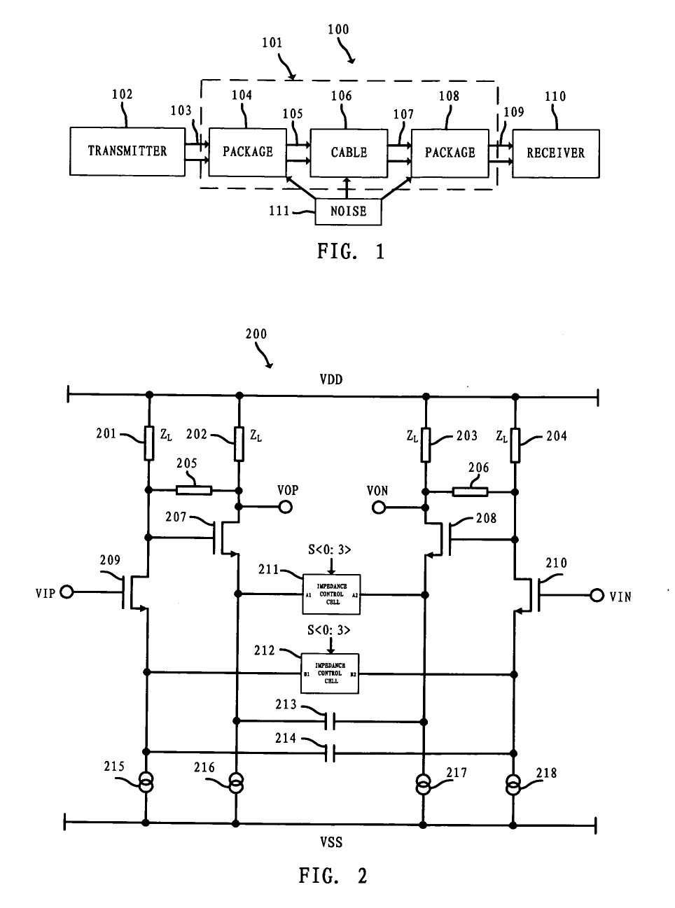

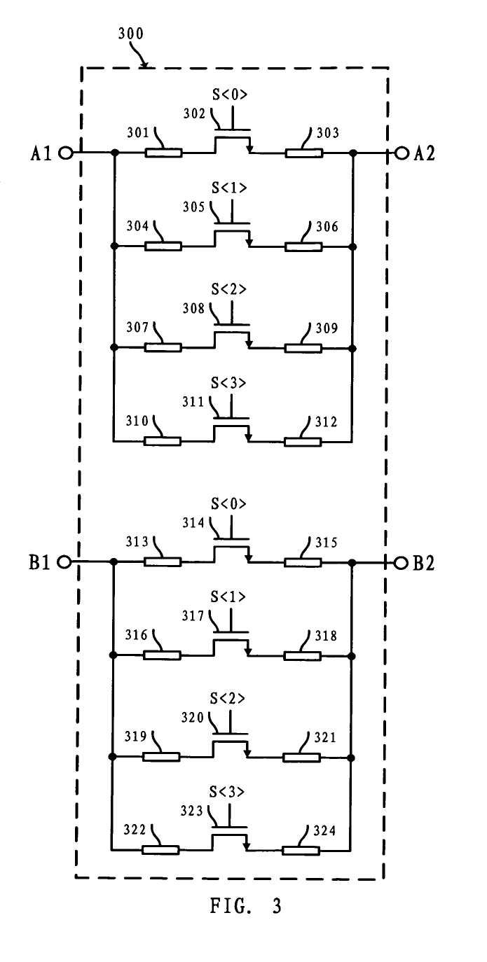

With reference to FIG. 2, a preferred embodiment of a receiver equalizer 200 is shown, and which comprises four transistors 207, 208, 209, 210 arranged as two differential pairs. Each transistor 207, 208, 209, 210 is connected to a current source 216, 217, 215, 218. Each pair of the two differential pairs has a capacitor 213, 214 and an impedance control cell 211, 212 connected to the current sources 216, 217, 215, 218 of the two differential pairs of transistors 207, 208, 209, 210. The equalizer 200 is also includes load impedances Z_{L} 202, 203, 201, 204 connected between the transistors 207, 208, 209, 210 and VDD rail. Each resistor 205, 206 functions as a negative impedance to extend bandwidth and achieve gain-peaking characteristics at the high frequency.

To restore the transmitted signal waveform in FIG. 1 at node 109 properly, the equalizer must present an output spectrum as close as an ideal one. In other words, the output of the equalizer can be programmable to determine whether the high-frequency part is under or over compensated and adjust the boost accordingly. With reference to FIG. 3, by changing the setting signals S<3:0>, the programmable impedance control cell can change the equalizer gain based on the cable length to optimize its output spectrum.

What is claimed is:

1. A receiver equalizer comprising, two pairs of current sources; and
two pairs of transistors arranged as two differential pairs, each transistor connected to a different one of the current sources; and
a pair of the capacitors connected between the current sources and the transistors of the two differential pairs; and
a parallel pair of the programmable impedance control cells connected to the two differential pairs.

2. A receiver equalizer as recited in claim 1 wherein the programmable impedance control cell comprises four parallel groups of resistor transistor network; and
the two ends of the four parallel groups of resistor transistor network connected together; and
wherein each group of resistor transistor network comprises one transistor and two resistors; and
the transistor sitting in the middle; and
its source connected to one resistor; and
its drain connected to anther resistor; and
its gate controlling by the programmable signal S.

3. A receiver equalizer as recited in claim 1 wherein the programmable impedance control cell can change the equalizer gain based on the cable length to optimize its output spectrum by changing the setting signals S<3:0>.
